(19) United States
(12) Patent Application Publication
(10) Pub. No.: US 2026/0361298 A1
(43) Pub. Date: Nov. 12, 2026

(54) FAULT DETECTION CONTROL DEVICE

(71) Applicant: LG INNOTEK CO., LTD., Seoul (KR)

(72) Inventors: In Seok IM, Seoul (KR); Won Kyu KIM, Seoul (KR)

(73) Assignee: LG INNOTEK CO., LTD., Seoul (KR)

(21) Appl. No.: 19/137,960

(22) PCT Filed: Nov. 30, 2023
(86) PCT No.: PCT/KR2023/019545

§ 371 Date: Jun. 11, 2025

(30) Foreign Application Priority Data
Dec. 22, 2022 (KR) 10-2022-0181507
Dec. 22, 2022 (KR) 10-2022-0181508

(51) Int. Cl. H03K 17/0814; G01R 19/165; G01R 31/52; H03K 17/08

(52) U.S. Cl. CPC H03K 17/08142; G01R 19/16519; G01R 31/52; H03K 2017/0806; H03K 2217/0027

(57) ABSTRACT

An embodiment of the present invention discloses a fault detection control device including a gate driver that outputs a driving signal to a switching driving circuit; a control unit that receives a temperature signal from a temperature sensor (TS) and senses a temperature abnormality; a detection unit that senses an overtemperature of a plurality of switching elements of the switching driving circuit; and an output unit connected to the control unit and the detection unit to output a control signal for turning on or off enabling to the gate driver.

### TECHNICAL FIELD

The present invention relates to a fault detection control device.

### BACKGROUND ART

With the release of eco-friendly passenger vehicles such as electric vehicles and hydrogen fuel cell vehicles, pure electric trucks or hydrogen fuel cell trucks equipped with an electric axle assembly are being developed as a type of eco-friendly commercial vehicle.

It is desirable that commercial vehicles having such an electric axle be developed to satisfy both driving performance and functions of existing commercial vehicles with diesel engines.

For example, there is a rocking free function for rough road escape among unique functions of existing diesel engine trucks, and this rocking free function should also be included in the commercial vehicles having the electric axle.

The rocking free function refers to a function of escaping from a rough road (muddy road, puddle, icy road, or the like) by using a reaction force obtained by repeating forward and backward movement when a vehicle cannot escape from the rough road because wheels of the vehicle are stuck on the rough road during driving of the vehicle.

It can be considered that the commercial vehicles having such an electric axle should be developed to a level that satisfies both the driving performance and function of the vehicle. Further, there is a demand for the stability of a vehicle having the electric axle that performs rough road escape, or the like.

Further, a disconnector controller detects a fault using a temperature sensor to protect the controller in case of overtemperature.

However, since the temperature sensor is located near a part of a PCB that generates significant heat (a reverse polarity prevention FET and a solenoid drive unit) to sense a temperature, there are limitations in measuring a temperature with respect to heat conduction and instantaneous current fluctuation.

### DISCLOSURE

### Technical Problem

The present invention is directed to providing a fault detection control device capable of controlling a gate driver even when a control unit (MCU) malfunctions in an overtemperature state through a sensing unit and a control unit, thereby reducing the possibility of component damage.

Further, the present invention is directed to providing a fault detection control device having improved reliability by sensing a short-circuit voltage of a switching element (for example, an FET), to thereby sense an instantaneous junction temperature change due to a change in load of the FET through a sensing unit, in addition to protecting elements against heat conduction.

Further, the present invention is directed to providing a fault detection control device that performs a short-circuit test with a battery on a connector terminal through a sensing unit and an output unit and does not malfunction.

Further, the present invention is directed to providing a fault detection control device having improved diagnostic coverage of a safety mechanism by sensing a fault through a control unit (MCU) and a sensing unit when an overvoltage or undervoltage fault occurs due to a connector terminal short-circuit.

The objects in the embodiments are not limited thereto, and it may be said that objects or effects that can be ascertained from the technical solution or embodiments below are also included.

### Technical Solution

A fault detection control device according to an aspect of the present invention includes a gate driver configured to output a driving signal to a switching driving circuit; a control unit configured to receive a temperature signal from a temperature sensor (TS) and sense a temperature abnormality; a detection unit configured to sense an overtemperature of a plurality of switching elements of the switching driving circuit; and an output unit connected to the control unit and the detection unit to output a control signal for turning on or off enabling to the gate driver.

The fault detection control device may include an amplification unit disposed between the switching elements and the detection unit.

The amplification unit may be connected between a drain and a source of each of the plurality of switching elements.

The amplification unit may amplify a voltage for a resistance (Rds(on)) between the drain and the source of each of the plurality of switching elements into a detection voltage.

The amplification unit may output the detection voltage to the control unit and the detection unit.

The control unit may output a first signal to the output unit when at least one of the temperature signal and the detection voltage is outside a preset range.

The detection unit may compare the detection voltage with a reference voltage to output a second signal to the output unit when an overtemperature is detected.

The output unit may output a signal for turning off enabling to the gate driver upon receiving at least one of the first signal and the second signal.

The plurality of switching elements of the switching driving circuit may output a control signal for a solenoid.

The amplification unit may be connected between a drain and a source of the switching element connected to the same node of the solenoid among the plurality of switching elements.

A fault detection control device according to an aspect of the present invention includes a power supply unit connected to a battery power supply; a control unit configured to receive a position signal from a position sensor and sense an abnormality of the position sensor; a sensing unit configured to receive the position signal and sense at least one of an undervoltage and an overvoltage; and an output unit connected to the control unit and the sensing unit and configured to output a control signal for turning on or off power supply to the power supply unit.

The control unit and the sensing unit may be connected to a common node.

The control unit may output a first signal when the position signal is outside a predetermined range.

The sensing unit may receive the position signal, and output a second signal when sensing at least one of an undervoltage and an overvoltage.

The output unit may output a control signal for turning off power supply to the power supply unit upon receiving at least one of the first signal and the second signal.

The sensing unit may include a gate element configured to receive the position signal and output the second signal when the position signal corresponds to at least one of the undervoltage and the overvoltage.

The sensing unit
may include a first resistor, a second resistor, and a third resistor that distribute the position signal and are sequentially connected in series; a first comparator that compares a voltage between the first resistor and the second resistor with a first reference voltage to sense the undervoltage; and a second comparator that compares a voltage between the second resistor and the third resistor with a second reference voltage to sense an overvoltage.

The first resistor may have resistance greater than the second resistor and the third resistor, and the third resistor may have resistance greater than the second resistor.

The first reference voltage may be smaller than the second reference voltage.

The first reference voltage may be lower than a third reference voltage for the control unit sensing an undervoltage, and
the second reference voltage may be higher than a fourth reference voltage for the control unit sensing an overvoltage.

### Advantageous Effects

According to an aspect of the present invention, it is possible to implement a fault detection control device capable of controlling a gate driver even when a control unit (MCU) malfunctions in an overtemperature state through a sensing unit and a control unit, thereby reducing the possibility of element damage.

Further, according to an aspect of the present invention, it is possible to implement a fault detection control device having improved reliability by sensing a short-circuit voltage of a switching element (for example, an FET), to thereby sense an instantaneous junction temperature change due to a change in load of the FET through a sensing unit, in addition to protecting elements against heat conduction.

Further, according to an aspect of the present invention, it is possible to implement a fault detection control device that accurately and quickly detects overtemperature.

Further, according to an aspect of the present invention, it is possible to implement a fault detection control device that detects a fault with hardware at the time of overtemperature and easily protects elements by disabling a gate driver (for example, drive unit).

Further, according to an aspect of the present invention, it is possible to implement a fault detection control device that performs a short-circuit test with a battery on a connector terminal through a sensing unit and an output unit and does not malfunction.

Further, according to an aspect of the present invention, it is possible to implement a fault detection control device having improved diagnostic coverage of a safety mechanism by sensing a fault through a control unit (MCU) and a sensing unit when an overvoltage or undervoltage fault occurs due to a connector terminal short-circuit.

The various beneficial advantages and effects of the present invention are not limited to the above-described content, and will be more easily understood from description of specific embodiments of the present invention.

### DESCRIPTION OF DRAWINGS

FIG. 1 is a block diagram of a fault detection control device, a solenoid, and a battery power supply according to a first embodiment.

FIG. 2 is a configuration diagram of the fault detection control device, the solenoid, and the battery power supply according to the first embodiment.

FIG. 3 is an operation flowchart of the fault detection control device according to the first embodiment.

FIGS. 4 and 5 are diagrams illustrating driving according to each state of the fault detection control device according to the first embodiment.

FIG. 6 is a block diagram of a fault detection control device, an actuator, and a battery power supply according to the second embodiment.

FIG. 7 is a configuration diagram of the fault detection control device, the actuator, and the battery according to the second embodiment.

FIG. 8 is a configuration diagram of the fault detection control device according to the second embodiment.

FIG. 9 is an operation flowchart of the fault detection control device according to the second embodiment.

FIGS. 10 and 11 are diagrams illustrating driving according to each state of the fault detection control device according to the second embodiment.

### MODES OF THE INVENTION

The present invention can be subject to various modifications and have several embodiments, and specific embodiments will be illustrated in the drawings and described. However, this is not intended to limit the present invention to specific embodiments, and the present invention should be understood to include all modifications, equivalents, and substitutions included in the spirit and technical scope of the present invention.

Terms including ordinal numbers such as “second” and “first” may be used to describe various components, but the components are not limited by the terms. The terms are used only for the purpose of distinguishing one component from another component. For example, a second component may be referred to as a first component, and similarly, a first component may also be referred to as a second component without departing from the scope of the present invention. The term “and/or” includes a combination of a plurality of related items that are described or any of the plurality of related items that are described.

When a component is said to be “connected” or “coupled” to another component, it should be understood that the component may be directly connected or coupled to the other component, or there may be other components disposed in between. On the other hand, when a component is said to be “directly connected” or “directly coupled” to another component, it should be understood that there are no other components disposed in between.

The terms used in the present application are used only to describe specific embodiments and are not intended to limit the present invention. A singular expression includes a plural expression unless the context clearly indicates otherwise. It should be understood that, in the present application, terms such as “include” and “have” are intended to designate the presence of a feature, number, step, operation, component, part, or combination thereof described in the specification, but do not preclude the possibility of the presence or addition of one or more other features, numbers, steps, operations, components, parts, or combinations thereof.

Unless otherwise defined, all terms used herein, including technical or scientific terms, have the same meanings as generally understood by those skilled in the art to which the present invention belongs. Terms such as those defined in generally used dictionaries should be construed as having meanings consistent with their meanings in the context of the related art, and are not to be construed as having ideal or excessively formal meanings unless explicitly defined in the present application.

Hereinafter, embodiments will be described in detail with reference to the accompanying drawings, the same or corresponding components will be denoted by the same reference signs throughout the drawings, and redundant description thereof will be omitted.

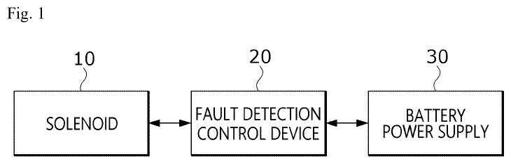

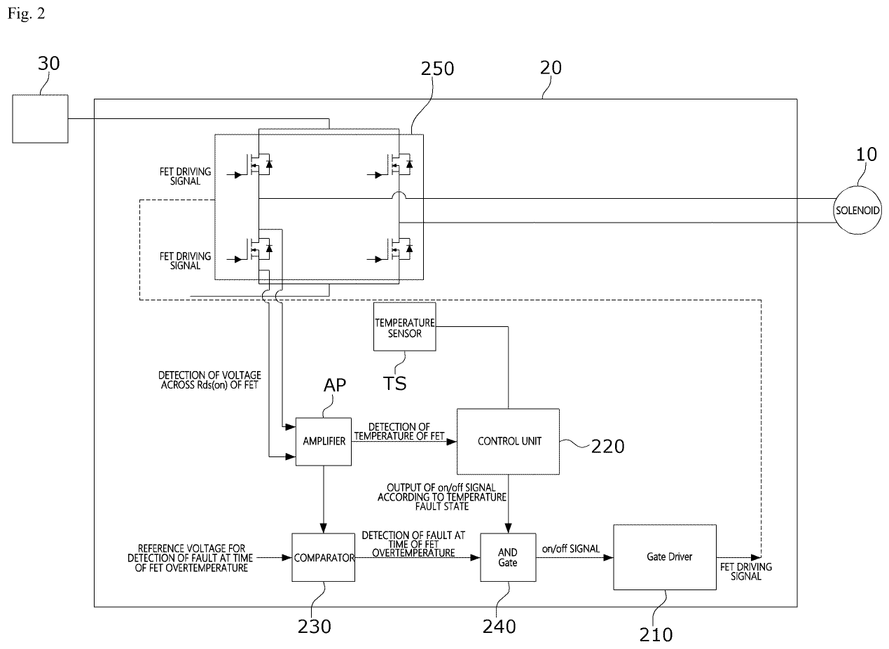

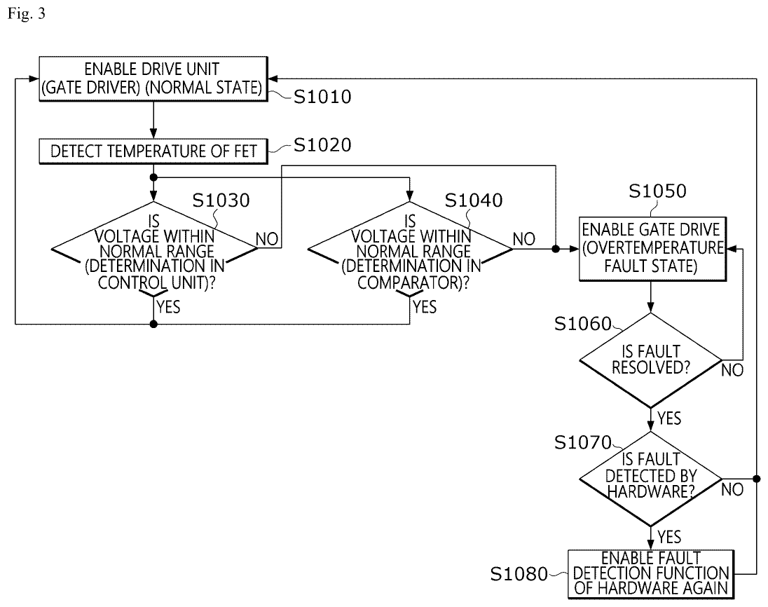

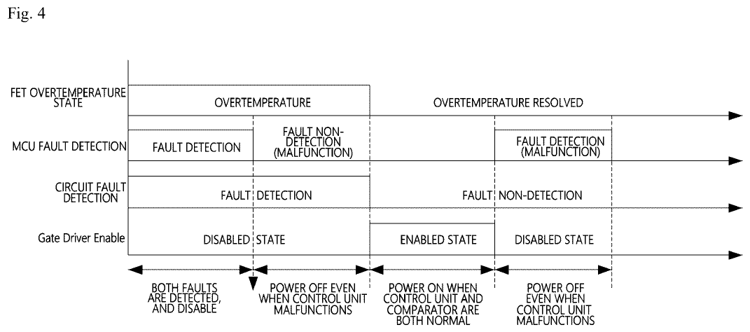

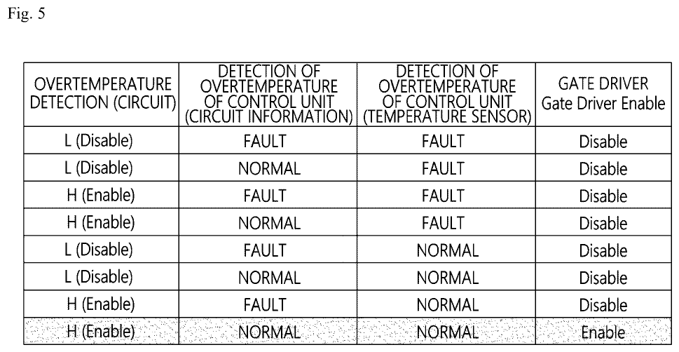

FIG. 1 is a block diagram of a fault detection control device, a solenoid, and a battery power supply according to a first embodiment, FIG. 2 is a configuration diagram of the fault detection control device, the solenoid, and the battery power supply according to the first embodiment, FIG. 3 is an operation flowchart of the fault detection control device according to the first embodiment, and FIGS. 4 and 5 are diagrams illustrating driving according to each state of the fault detection control device according to the first embodiment.

First, the fault detection control device according to the first embodiment of the present invention, a battery (or battery power supply) connected to the fault detection control device, and a solenoid may be disposed in a vehicle.

The fault detection control device according to the first embodiment may control the solenoid connected to, for example, a torque control that is applied to the vehicle. Further, the fault detection control device according to the first embodiment may be applied to various types of vehicles (for example, a hybrid vehicle, a plug-in hybrid vehicle, an electric vehicle, and an internal combustion engine vehicle).

Referring to FIGS. 1 and 2, the vehicle according to the first embodiment may include a solenoid, a fault detection control device 20, and a switching driving circuit 250. The fault detection control device 20 may be connected to the solenoid through a connector. The fault detection control device 20 may provide power supplied from the switching driving circuit 250 to a temperature sensor TS of the solenoid through the connector according to an output of the gate driver.

More specifically, the solenoid according to the first embodiment may include a motor and the temperature sensor TS 10. The transmission, torque (rotation), and the like of the vehicle may be controlled through a solenoid valve.

The motor may control wheels of the vehicle, a torque of the wheels, or the like. This makes escape from narrow terrain easier. The temperature sensor TS 10 may be disposed adjacent to the motor to detect position information according to rotation of the motor. The temperature sensor TS may include, for example, a Hall sensor. Accordingly, the temperature sensor TS may output a temperature signal. The temperature signal may be a voltage signal. For example, the temperature signal can have a voltage range of 0 to 5 V in a normal state.

In the fault detection control device, when a switch (or element) for enabling cannot be controlled because of a malfunction due to a fault, internal elements are likely to be damaged. In terms of functional safety, determining a fault with a single signal has low diagnostic coverage and thus does not satisfy ASIL level requirements.

The fault detection control device 20 according to the first embodiment may detect an overtemperature (overcurrent or undercurrent) or the like when the control unit is faulty, and block or turn off the enabling of the gate driver, thereby protecting elements, when determining that the control unit is faulty. For example, a drain current of a switching element (FET) tends to decrease at a high temperature. Further, there may be various current changes corresponding to the temperature depending on the switching element. For example, a current may decrease when a temperature of the switching element increases. The enabling of the gate driver may correspond to on or off of a driven state of the gate driver. For example, in an off state, a gate driver 210 does not output a switching drive signal to the switching driving circuit 250.

The fault detection control device 20 according to the first embodiment may include the gate driver 210, a control unit 220, a detection unit 230, an output unit 240, the switching driving circuit 250, the temperature sensor TS TS, and an amplification unit AP.

The gate driver 210 may output the driving signal to the switching driving circuit 250. For example, the gate driver 210 may output the driving signal to each of a plurality of switching elements of the switching driving circuit 250. The plurality of switching elements may output a control signal for the solenoid. The gate driver 210 may be called a driving driver for the switching driving circuit. The gate driver 210 may be connected to the switching driving circuit 250. The gate driver 210 may receive a control signal for turning on or off the enabling from the output unit 240. The control signal for turning on or off the enabling may be provided to the gate driver 210. For example, when the gate driver 210 receives the control signal for turning on the enabling from the output unit 240, the gate driver 210 may output the driving signal (or FET driving signal) to the switching driving circuit 250. On the other hand, when the gate driver 210 receives a control signal for turning off enabling from the output unit 240, the gate driver 210 may not output the driving signal (or FET driving signal) to the switching driving circuit 250.

The control unit 220 may receive the temperature signal from the temperature sensor TS to detect a temperature abnormality. The control unit 220 may receive the temperature signal (for example, voltage or current) when the temperature is high or the temperature signal when the temperature is normal. Based on this, the control unit 220 may output a signal for determining a control signal for turning on or off the gate driver 210 to the output unit 240 before the gate driver 210. For example, the control unit 220 may output a first signal to the output unit 240. That is, the control unit 220 may output the first signal when the temperature signal is outside a predetermined range (a short-circuit voltage detection or the like). The first signal may be an off control signal.

Further, the control unit 220 may output the first signal when a detection voltage is outside a preset range. The detection voltage may correspond to a voltage between a source and a drain in the switching element of the switching driving circuit. Alternatively, the detection voltage may correspond to a voltage obtained by the amplification unit AP amplifying the voltage between the source and the drain.

In an embodiment, the control unit 220 may output the first signal to the output unit 240 when at least one of the temperature signal and the detection voltage is outside the preset range.

The detection unit 230 may detect an overcurrent of the plurality of switching elements (for example, FETs) of the switching driving circuit 250. For example, the detection unit 230 may include a comparator. The detection unit 230 may receive the voltage between the source and the drain of the switching element or the detection voltage to detect overcurrent (or overtemperature). In the present specification, the overcurrent (overtemperature) corresponds to a state in which a temperature of the control device 20 is equal to or higher than a predetermined temperature.

The detection unit 230 may output a second signal when the detection unit 230 receives the temperature signal and detects the overcurrent. The second signal may be provided to the output unit 240.

The output unit 240 may be connected to the control unit 220 and the detection unit 230 to output the control signal for turning on or off the enabling to the gate driver 210. As described above, when the output unit 240 outputs the on signal to the gate driver 210, the driving signal for the switching element, that is, the FET driving signal, may be provided from the gate driver 210 to the switching driving circuit 250. When the output unit 240 receives at least one of the first signal and the second signal, the output unit 240 may output the signal for turning off enabling to the gate driver 210. In this case, the switching driving circuit 250 may not output the driving signal to the switching driving circuit 250. That is, the power supply to the gate driver 210 may be cut off.

The output unit 240 may be an AND gate or a NAND gate. Accordingly, the output unit 240 may output an on signal when the output unit 240 receives neither the first signal nor the second signal. As will be described below, a type of gate may be changed depending on a target of True (high) or False (low).

The detection unit 230 may compare the voltage between the drain and the source of each of the plurality of switching elements of the switching driving circuit 250 with a reference voltage to detect overcurrent or overtemperature. The detection unit 230 may output the second signal to the output unit 240 when the overcurrent is detected by comparing the detection voltage with the reference voltage.

When the overcurrent is detected, the fault detection control device 20 may switch to a fault state and output a control signal for turning off the gate driver 210 that supplies the driving signal to the switching driving circuit 250. Accordingly, the fault detection control device 20 may remain in the fault state until the fault detection control device 20 is initialized.

The fault detection control device 20 may detect an overtemperature even when the control unit 220 does not detect an overtemperature state due to a fault.

That is, when the fault detection control device 20 detects a fault and the control unit 220 is not operating normally, the output unit 240 may output the control signal to turn off the gate driver 210 that supplies the switching driving circuit 120 based on the second signal of the detection unit 230 instead of the control unit 220. The fault state may be maintained until the control unit 220 operates normally. When the fault state is not maintained, the switching driving circuit may be supplied again due to a malfunction of the control unit 220, causing a fault. The fault detection control device 20 may output a fault state signal to the control unit 220 or the outside so that the control unit 220 can recognize that the fault has occurred before normal operation, when the control unit 220 returns to the normal operation.

When the comparator, that is, the detection unit 230, detects overtemperature, which indicates a fault state, various elements may be applied to block the enabling.

Further, the output unit 240 may also be configured of various logic elements. For example, the output unit 240 may be an AND gate. The AND gate may be a logic gate that outputs False when one of inputs is false, and outputs True when both of the inputs are true. That is, when at least one of the first signal and the second signal is input to the output unit 240, the output unit 240 may output False. That is, when overtemperature is not detected from either of the temperature sensor TS and the switching element, the output unit 240 may output True. However, True and False may be interchanged depending on a setting of the detection unit 230 or the control unit 220. Low may correspond to False. Also, High may correspond to True. For example, when both the detection unit 230 and the control unit 220 output High (True or fault non-detection), the output unit 240 may output True or High (fault non-detection) to the gate driver 210. When at least one Low (False or fault non-detection) is output from the detection unit 230 and the control unit 220, the output unit 240 may output False or Low (fault detection) to the gate driver 210. This makes it possible for the fault detection control device 20 to detect a fault more simply and efficiently.

The amplification unit AP may be disposed between the switching element of the switching driving circuit 250 and the detection unit 230. The amplification unit AP may be connected to both the drain and source of each of the plurality of switching elements. For example, the amplification unit AP may amplify the voltage for resistance (Rds(on)) between the drain and the source of each of the plurality of switching elements into the detection voltage. Accordingly, the amplification unit AP may output the detection voltage to the control unit 220 and the detection unit 230. Accordingly, the control unit 220 and the detection unit 230 can more accurately determine whether or not there is an overtemperature at the FET. Further, the protection of the control device 20 against the temperature can be further improved.

As an example, the amplification unit AP may be connected between the drain and the source of the switching element connected to the same node of the solenoid among the plurality of switching elements. Accordingly, the temperature of the control device 20 can be continuously detected even during various operations of the solenoid 10. That is, the reliability of the control device according to the first embodiment can be improved.

Referring back to FIG. 3, the fault detection control device 20 may be set to detect a fault even when the control unit 220 does not operate normally. First, in the fault detection, the gate driver which is a drive unit is enabled so that the driving signal can be provided to the switching driving circuit 250 (S1010). This is assumed to be a normal state in the description. A temperature signal may be received (S1020). That is, the temperature signal may be a voltage of the switching element (FET) or the temperature signal from the temperature sensor.

The control unit may determine whether the voltage (the temperature signal) is within a normal range (S1030) (determination in the control unit or MCU). Further, the detection unit (comparator) may determine whether the voltage (the temperature signal) is within the normal range (S1040) (the determination in the comparator or the detection circuit). When the temperature signal is within the normal range, the gate driver may output the driving signal to the switching driving circuit.

However, when the temperature signal (voltage) is outside the normal range, it may be determined that there is a fault. Enabling of the gate driver can be turned off or blocked (S1050).

Thereafter, it may be determined whether the fault is cleared or resolved (S1060). This may be performed after a predetermined time or at predetermined time intervals. For example, the fault resolving may be determined depending on, for example, whether temporary enabling or power non-supply is accurately detected.

The control unit may determine whether the control unit, the detection unit, and the output unit that are hardware have detected a fault. When the control unit and the detection unit have not detected a fault, the gate driver may be turned on. On the other hand, when the control unit, detection unit, and detection unit detect a fault and remain in the fault state, the fault detection function is enabled again (S1080) and then an on control signal is output to the gate driver so that the driving signal can be output to the switching driving circuit.

Fault detection drive may be performed as illustrated in FIGS. 4 and 5. The overtemperature (overcurrent; fault state) may be a fault state. When this fault determination is accurately made, the fault may be detected when the operation of the control unit is normal. That is, the control unit (corresponding to MCU fault detection) may output a first signal (low or false (corresponding to disable)) to the output unit. The detection unit (corresponding to circuit fault detection) may detect an overtemperature corresponding to an undervoltage or overcurrent between the drain and the source of the switching element. The detection unit may output a second signal (low or false (corresponding to disable). Accordingly, the output unit may output an off signal to the gate driver. The first signal may be output from the control unit when it is determined that overtemperature occurs by comparing both signals from both the switching element and the temperature sensor with the predetermined range. That is, the control unit may detect an overtemperature through not only the switching element but also the temperature sensor, like the detection unit. For example, the control unit (MCU) may perform both the overtemperature (circuit information) detection of the switching element and the overtemperature detection of the temperature sensor. The control unit (MCU) may output High or True to the output unit when neither is detected (fault). When at least one overtemperature is detected, the control unit may output False or Low to the output unit.

Further, in the case of overtemperature (fault state), even when the control unit fails and malfunctions, the detection unit may detect overcurrent corresponding to a battery short-circuit. Accordingly, the detection unit may output the second signal. However, the control unit may not output the first signal. However, the control unit may output the first signal through the temperature sensor. In this case, the output unit may output the off signal to the gate driver. The first signal or True (high) of non-detection from the control unit may be output to the output unit. In this case, when the second signal, which is a signal from the detection unit, is False (low), the output unit may output an off control signal to the gate driver even when neither the first signal nor the second signal from the control unit or the detection unit is provided to the output unit. That is, the malfunction of the control unit can be easily detected.

Further, in a normal state in which overtemperature has been resolved, it is possible to accurately detect whether the control unit malfunctions due to a fault.

For example, since the detection unit is in the normal state, overcurrent corresponding to overtemperature may not be detected at all at a normal temperature. Accordingly, the detection unit may not output the second signal (True (high)). That is, the detection unit may output False (low). The control unit may not output the first signal. That is, the control unit may output False (low). In this case, the output unit may output a signal for turning on the enabling to the gate driver. The gate driver may remain on. In other words, when both the control unit and the detection unit are normal, the enabling may be on in the normal state. That is, when the detection unit outputs a True (high) signal to the output unit and the control unit outputs a True (high) signal to the output unit, the output unit may output an on control signal of the gate driver to the gate driver. In other cases, the output unit may output an off control signal.

However, when the control unit malfunctions, the detection unit may not output the second signal. However, the control unit may output the first signal. The output unit may output an off signal to the gate driver. That is, the control unit may output True (high) corresponding to the first signal to the output unit. The detection unit may output False (low), not the second signal, to the output unit. In this case, the output unit may output the off control signal to the gate driver. That is, the malfunction of the control unit can be easily detected.

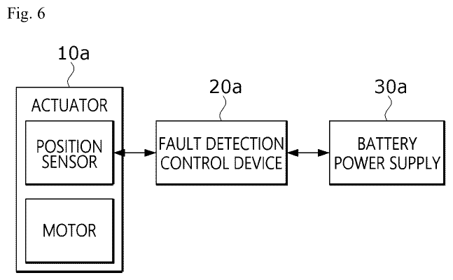

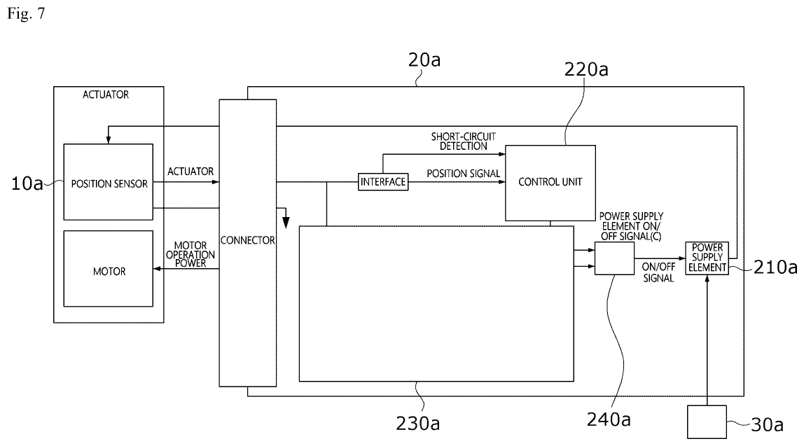

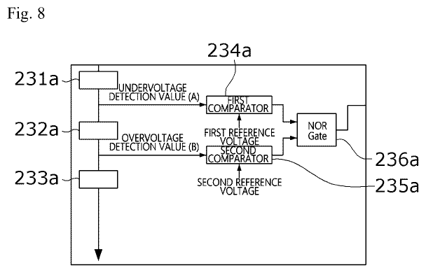

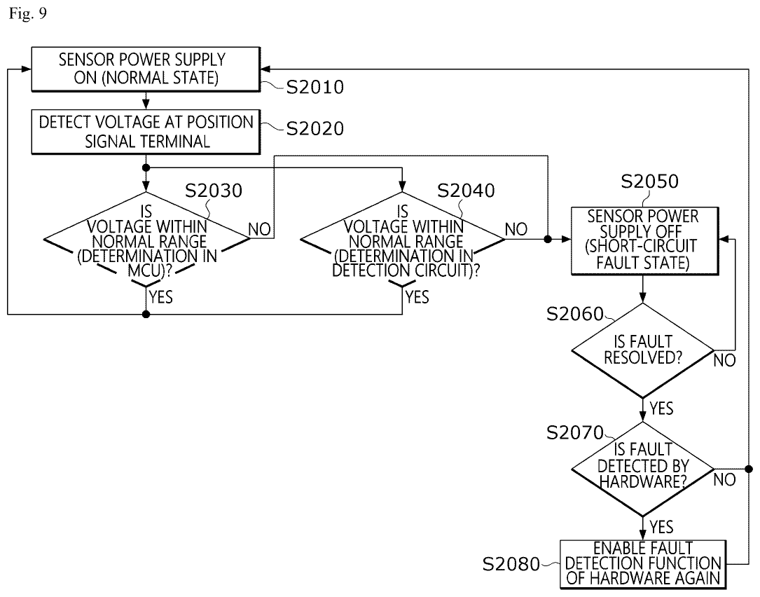

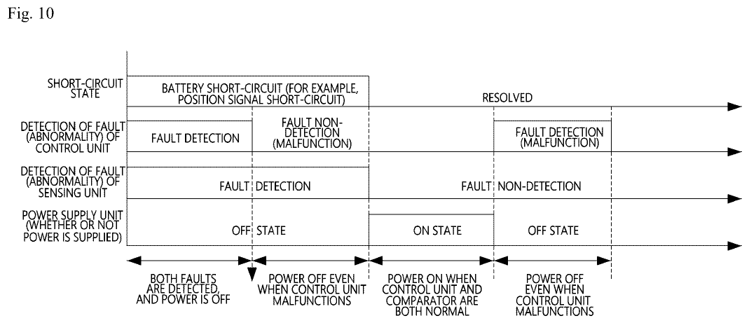

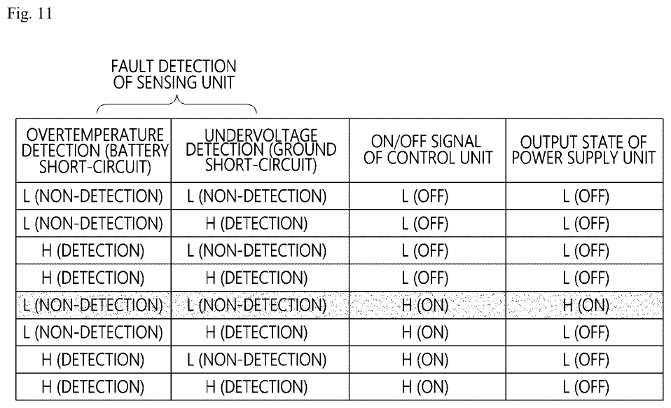

FIG. 6 is a block diagram of a fault detection control device, an actuator, and a battery power supply according to a second embodiment, FIG. 7 is a configuration diagram of the fault detection control device, the actuator, and the battery according to the second embodiment, FIG. 8 is a configuration diagram of the fault detection control device according to the second embodiment, FIG. 9 is an operation flowchart of the fault detection control device according to the second embodiment, and FIGS. 10 and 11 are diagrams illustrating driving according to each state of the fault detection control device according to the second embodiment.

First, the fault detection control device according to the second embodiment of the present invention, a battery connected to the fault detection control device, and the actuator (position sensor and motor) may be disposed in a vehicle.

The fault detection control device according to the second embodiment may control a motor for torque control that is applied to the vehicle. Further, the fault detection control device according to the second embodiment may be applied to various types of vehicles (for example, a hybrid vehicle, a plug-in hybrid vehicle, an electric vehicle, and an internal combustion engine vehicle).

Referring to FIGS. 6 and 7, the vehicle according to the second embodiment may include an actuator, a fault detection control device 20a, and a battery power supply 30a. The fault detection control device 20a may be connected to the actuator through a connector. The fault detection control device 20a may provide power supplied from the battery power supply 30a to a position sensor of the actuator through the connector according to an output of the power supply unit.

More specifically, the actuator according to the second embodiment may include a motor and a position sensor 10a. The motor may control wheels of the vehicle, a torque of the wheels, or the like. This makes escape from narrow terrain easier. The position sensor 10a may be disposed adjacent to the motor to detect position information according to rotation of the motor. The position sensor may include, for example, a Hall sensor. Accordingly, the position sensor may output a position signal. The position signal may be a voltage signal. For example, the position signal may have a voltage range of 0 V to 5 V in a normal state.

When the fault detection control device malfunctions due to a fault and the control of a switch (or element) for power supply becomes impossible, internal elements are likely to be damaged. In terms of functional safety, determining a fault with a single signal has low diagnostic coverage and thus does not satisfy the ASIL level requirements.

The fault detection control device 20a according to the second embodiment can detect overvoltage, undervoltage, or the like even when the connector or control unit is faulty, and cut off the power supply upon determining that the connector or control unit is faulty to protect elements.

The fault detection control device 20a according to the second embodiment may include a power supply unit 210a, a control unit 220a, a sensing unit 230a, and an output unit 240a.

The power supply unit 210a may be called a power supply element. The power supply unit 210a may be connected to the battery power supply 30a to supply power to the motor or position sensor. The power supply unit 210a may perform power supply to the position sensor by receiving a control signal for turning on or off the power supply from the output unit 240a. For example, when the power supply unit 210a receives the control signal for turning on the power supply from the output unit 240a, power may be supplied to the position sensor through the connector. On the other hand, when the power supply unit 210a receives the control signal for turning off the power supply from the output unit 240a, power supply to the position sensor through the connector can be cut off.

The control unit 220a may receive the position signal from the position sensor and detect an abnormality of the position sensor. The control unit 220a may obtain a short-circuit voltage detection value via an interface in the case of a fault or receive the position signal in the case of a normal state the position signal received through the connector. Based on this, the control unit 220a may output a signal for determining the control signal for turning on or off the power supply unit 210a to the output unit 240a before the power supply unit 210a (or power supply element). For example, the control unit 220a may output the first signal to the output unit 240a. That is, the control unit 220a may output the first signal when the position signal is outside a predetermined range (short-circuit voltage detection a). The first signal may be an off control signal.

The sensing unit 230a may receive the position signal from the position sensor to detect at least one of the undervoltage and the overvoltage. The sensing unit 230a may output the second signal when the sensing unit 230a receives the position signal to detect at least one of the undervoltage and the overvoltage. The second signal may be provided to the output unit 240a.

The output unit 240a may be connected to the control unit 220a and the sensing unit 230a to output the control signal for turning on or off the power supply to the power supply unit 210a. As described above, when the output unit 240a outputs an on signal to the power supply unit 210a, power from the battery power supply 30a may be supplied to the position sensor through the connector. When the output unit 240a receives at least one of the first signal and the second signal, the output unit 240a may output a signal for turning off the power supply to the power supply unit 210a. In this case, the power supply from the battery power supply 30a may be cut off.

The output unit may include a logic gate element or circuit. For example, the output unit 240a may be a NAND or AND gate. Accordingly, the output unit may output an on signal when neither the first signal nor the second signal is received. As will be described below, a type of gate may be changed depending on a target of True (high) or False (low).

The battery power supply 30a may be located in the vehicle. Further, the battery power supply 30a may be connected to the power supply unit.

More specifically, referring back to FIGS. 8 and 9, the control unit 220a and the sensing unit 230a may be connected to a common node. That is, the control unit 220a and the sensing unit 230a may be connected to the same line or the same node for detecting or transmitting the position signal from the position sensor. It is possible to provide a fault detection control device with further improved safety through the control unit 220a and the sensing unit 230a, and a vehicle including the same.

The sensing unit 230a may include a plurality of resistors, a first comparator 234a, a second comparator 235a, and a gate element 236a.

The plurality of resistors may include a first resistor 231a, a second resistor 232a, and a third resistor 233a. The first resistor 231a, the second resistor 232a, and the third resistor 233a may distribute the position signal and may be sequentially connected in series. The first resistor 231a may be connected or located most adjacent to the connector for outputting the position signal.

The first comparator 234a may compare a voltage between the first resistor 231a and the second resistor 232a with a first reference voltage to detect an undervoltage.

The second comparator 235a may compare a voltage between the second resistor 232a and the third resistor 233a with a second reference voltage to detect an overvoltage.

The gate element 236a may receive the position signal and output the second signal when the position signal corresponds to at least one of the undervoltage and the overvoltage.

The plurality of resistors may include the first resistor 231a, the second resistor 232a, and the third resistor 233a connected in series. The first comparator 234a may compare a voltage at a node between the first resistor 231a and the second resistor 232a with the first reference voltage, to sense such a sensed voltage as an undervoltage when the sensed voltage is smaller than the first reference voltage. The second comparator 235a may compare a voltage at a node between the second resistor 232a and the third resistor 233a with the second reference voltage, to sense such a sensed voltage as an overvoltage when the sensed voltage is higher than the second reference voltage.

When at least one of the undervoltage and the overvoltage is sensed, the fault detection control device 20a may switch to the fault state and may output a control signal for turning off the power supply unit 210a that supplies the battery power supply 30a. Accordingly, the fault detection control device 20a may remain in the fault state until initialization.

The fault detection control device 20a may sense at least one of the undervoltage and the overvoltage that the control unit 220a has failed to sense when the control unit 220a has failed to sense the at least one of the undervoltage and the overvoltage due to a fault. To this end, the first reference voltage may be set to be lower than a third reference voltage for the control unit sensing the undervoltage, and the second reference voltage may be set to be higher than a fourth reference voltage for the control unit sensing the overvoltage.

That is, when the fault detection control device 20a senses a fault and the control unit 220a is not operating normally, the output unit 240a may output the control signal for turning off the power supply unit 210a that supplies the battery power supply 120a based on the second signal of the sensing unit 230a instead of the control unit 220a. The fault state may be maintained until the control unit 220a returns to normal operation. When the fault state is not maintained, battery power may be supplied again due to a malfunction of the control unit 220a, which may cause a fault. The fault detection control device 20a may output a fault state signal to the control unit 220a or the outside so that the control unit 220a can recognize that the fault has occurred before normal operation, when the control unit 220a returns to the normal operation.

When at least one of the first comparator 234a and the second comparator 235a senses a fault, which indicates the fault state, the gate element 236a may be used to cut off the power supply.

The gate element 236a may be any of a variety of signal gate elements, such as a NOR gate. The NOR gate may be a logic gate that outputs False when one of inputs is True and outputs True when both of the inputs are False. That is, when at least one of the first comparator 234a and the second comparator 235a senses a fault, the comparator outputs a fault detection signal. For example, when the voltage is low, the first comparator 234a may output Low or False. However, True and False may be interchanged depending on a setting of the first comparator. Low may correspond to False. Also, High may correspond to True. For example, when both the first comparator 234a and the second comparator 235a output Low (False or non-detection of fault), the gate element 236a may output True or High (non-detection a fault) to the output unit 240a.

Thus, the sensing unit 230a may simultaneously sense the undervoltage and the overvoltage through voltage distribution. In an embodiment, the first resistor may have greater resistance than the second and third resistors, and the third resistor may have greater resistance than the second resistor. This makes it possible to sense the undervoltage and the overvoltage efficiently. Further, the first reference voltage may be smaller than the second reference voltage. This makes it possible for the fault detection control device 20a to detect a fault more simply and efficiently.

Referring further to FIG. 9, the fault detection control device 20a may be set to detect a fault when the control unit 220a does not operate normally. First, in the fault detection, power may be preferentially supplied to the position sensor (S2010). This is assumed to be a normal state in the description. The position signal may be received (S2020). That is, a voltage of the position signal may be detected. In this case, a fault can be detected through the control unit and the sensing unit connected to the same node.

The control unit may determine whether the voltage (the position signal) is within the normal range (S2030) (the determination in the control unit or MCU). Further, the sensing unit may determine whether the voltage (the position signal) is within the normal range (S2040) (the determination in the sensing unit or detection circuit). When the position signal is within the normal range, power may be supplied to the position sensor.

However, when the position signal (the voltage) is outside the normal range, a fault may be determined to have occurred. The power supply to the position sensor may be turned off or cut off (S2050). For example, this may be determined to be a short-circuit fault state.

Thereafter, it may be determined whether the fault is cleared or resolved (S2060). This may be performed after a predetermined time or at predetermined time intervals. For example, the fault resolving may be determined depending on, for example, whether temporary power supply or power non-supply is accurately detected.

The control unit 220a may determine whether the sensing unit and the output unit, which are hardware, have detected the fault. When the sensing unit and the detection unit have not detected the fault, the power supply unit may be turned on. On the other hand, when the sensing unit and the detection unit have detected the fault and the fault state remains, the fault detection function may be enabled again (S2080), and then the on control signal may be output to the power supply unit so that power can be supplied to the position sensor.

The fault detection driving may be performed as in FIGS. 10 and 11. When the battery is short-circuited (for example, position signal short-circuit), a fault may be determined to have occurred. When this fault determination is accurately performed and the control unit operates normally, the fault can be detected. That is, the control unit may output the first signal to the output unit. The sensing unit may detect at least one of the undervoltage and the overvoltage corresponding to the battery short-circuit. The sensing unit may output the second signal. Accordingly, the output unit may output the off signal to the power supply unit.

Further, in the case of the fault state (battery short-circuit), the sensing unit can detect at least one of the undervoltage and the overvoltage corresponding to the battery short-circuit even when the control unit malfunctions. Accordingly, the sensing unit may output the second signal. However, the control unit may not output the first signal. However, the output unit may output the off signal to the power supply unit. That is, when the signal from the control unit is True (high) and the signal from the sensing unit, which is the second signal, is False (low), the output unit may output the off control signal to the power supply unit even when neither the first signal nor the second signal from the control unit and the detection unit is provided to the output unit malfunction. That is, it is possible to achieve ease of protection even when the control unit malfunctions.

On the other hand, in the normal state in which the battery short-circuit is resolved, it is possible to accurately sense whether the control unit malfunctions due to a fault.

For example, since the sensing unit is in a normal state, neither the undervoltage nor the overvoltage corresponding to the battery short-circuit may be detected. Accordingly, the sensing unit may not output the second signal (True (high)). That is, the sensing unit may output False (low). The control unit may not output the first signal. That is, the control unit may output False (low). In this case, the output unit may output the on signal for power supply to the power supply unit. The power supply unit may remain on. In other words, when both the control unit and the sensing unit are normal, the power supply may be in an on state in the normal state. That is, when the output unit receives a True (high) signal from the sensing unit and the True (high) signal from the control unit, the output unit may output the on control signal for the power supply unit to the power supply unit. In other cases, the output unit may output the off control signal.

However, when the control unit malfunctions, the control unit may output the first signal. The output unit may output the off signal to the power supply unit. That is, when the first signal is True (high) and the second signal is False (low), the output unit may output the off control signal to the power supply unit. That is, it is possible to easily detect the malfunction of the control unit.

The embodiments have been mainly described above, but this is only an example and does not limit the present invention, and it will be understood by those skilled in the art to which the present invention pertains that various modifications and applications not illustrated above are possible without departing from the essential characteristics of the present embodiments. For example, respective components specifically shown in the embodiments can be modified and implemented. Differences related to such modifications and applications should be construed as being included in the scope of the present invention defined in the appended claims.

1. A fault detection control device comprising:
a gate driver configured to output a driving signal to a switching driving circuit;
a control unit configured to receive a temperature signal from a temperature sensor (TS) and sense a temperature abnormality;
a detection unit configured to sense an overtemperature of a plurality of switching elements of the switching driving circuit; and
an output unit connected to the control unit and the detection unit to output a control signal for turning on or off enabling to the gate driver.

2. The fault detection control device of claim 1, comprising:
an amplification unit disposed between the switching elements and the detection unit.

3. The fault detection control device of claim 2, wherein the amplification unit is connected between a drain and a source of each of the plurality of switching elements.

4. The fault detection control device of claim 2, wherein the amplification unit amplifies a voltage for a resistance (Rds(on)) between a drain and a source of each of the plurality of switching elements into a detection voltage.

5. The fault detection control device of claim 4, wherein the amplification unit outputs the detection voltage to the control unit and the detection unit.

6. The fault detection control device of claim 5, wherein the control unit outputs a first signal to the output unit when at least one of the temperature signal and the detection voltage is outside a preset range.

7. The fault detection control device of claim 6, wherein the detection unit compares the detection voltage with a reference voltage to output a second signal to the output unit when an overtemperature is sensed.

8. The fault detection control device of claim 7, wherein the output unit outputs a signal for turning off enabling to the gate driver upon receiving at least one of the first signal and the second signal.

9. The fault detection control device of claim 2, wherein the plurality of switching elements of the switching driving circuit output a control signal for a solenoid.

10. The fault detection control device of claim 9, wherein the amplification unit is connected between a drain and a source of the switching element connected to the same node of the solenoid among the plurality of switching elements.

11. The fault detection control device of claim 1, wherein when the output unit outputs an on signal to the gate driver, the gate driver provides a driving signal to the switching drive circuit.

12. The fault detection control device of claim 8, wherein the gate driver does not output a driving signal to the switching drive circuit.

13. The fault detection control device of claim 7, wherein the output unit outputs an on signal when neither the first signal nor the second signal is received.

14. The fault detection control device of claim 7, wherein the control unit outputs a fault state signal when the deactivation (off) signal is output.

15. The fault detection control device of claim 1, wherein the output unit comprises an AND gate or a NAND gate.

16. The fault detection control device of claim 7, wherein the detection unit outputs the second signal even when the control unit does not output the first signal.

17. The fault detection control device of claim 1, wherein the detection unit detects an overcurrent corresponding to a battery short-circuit and outputs the second signal even if the control unit malfunctions.

18. The fault detection control device of claim 1, wherein the control unit detects both the overtemperature of the switching elements and the overtemperature from the temperature sensor.

19. The fault detection control device of claim 1, wherein current flowing through the switching elements decreases as the temperature of the switching elements increases.

20. The fault detection control device of claim 1, wherein the temperature sensor is disposed adjacent to a motor and includes a hall sensor.
